(19) United States
(12) Patent Application Publication
(10) Pub. No.: US 2008/0116470 A1
(43) Pub. Date: May 22, 2008

(54) SEMICONDUCTOR LIGHT EMITTING DEVICE

(75) Inventor: Yoshiro NISHIMURA, Nagano (JP)

Correspondence Address: SCULLY SCOTT MURPHY & PRESSER, PC, 400 GARDEN CITY PLAZA, SUITE 300, GARDEN CITY, NY, 11530, US

(73) Assignee: OLYMPUS CORPORATION, Tokyo (JP)

(21) Appl. No.: 11/939,831

(22) Filed: Nov. 14, 2007

(30) Foreign Application Priority Data
Nov. 20, 2006 (JP) 2006-313590

(51) Int. Cl. H01L 33/00

(52) U.S. Cl. 257/89; 257/88; 257/E33.001

(57) ABSTRACT

The semiconductor light emitting device includes a plurality of transparent light emitting elements of the same size which are arranged in a layered manner on an electric substrate by using a wire bonding. On one of the light emitting elements including a bonding wire connected to a bonding pad of the light emitting element, another one of the light emitting elements is layered with a transparent resin layer interposed therebetween, and on the another one of the light emitting elements, yet another one of the light emitting elements is layered in the same state. Emitting lights of the light emitting elements on a lower side transmit the light emitting elements on an upper side, and emitting light of the light emitting element positioned uppermost directly irradiates a surface to be irradiated. Therefore, there is no restriction in size, and high-luminance light emitting elements are mounted in a smaller area.

This application claims benefit of Japanese Application No. 2006-313590 filed in Japan on Nov. 20, 2006, the contents of which are incorporated by this reference.

### BACKGROUND OF THE INVENTION

1. Field of the Invention

The present invention relates to a semiconductor light emitting device using a plurality of light emitting elements.

2. Description of the Related Art

As a conventional structure of a semiconductor light emitting device in which light emitting elements are mounted in a layered mariner, Japanese Unexamined Patent Application Publication No. 2003-197968 discloses a package structure of a light emitting diode light source. As shown in the cross-sectional view of a light source package in FIG. 6, a light source package 100 has a structure in which a light emitting element 103 is arranged on a package substrate 101 with a reflective plate 102 interposed therebetween, and on the light emitting element 103 are further stacked light emitting elements 104 and 105 which are directly bonded with transparent electrodes 106, 107, respectively. Out of the light emitting elements 103, 104, and 105 arranged in a layered manner, the light emitting elements arranged on upper layers are formed smaller in size than the light emitting elements arranged on lower layers so as to avoid areas of bonding pads 108, 109 of the light emitting elements on the lower layers.

On the other hand, as a conventional semiconductor light emitting device, a light emitting device having a structure in which a plurality of light emitting diodes are flatly arranged on a substrate can be considered as shown in the side view of the light emitting device in FIG. 7. The conventional light emitting device has a structure in which red, green, and blue light emitting elements 122, 123, and 124 are adjoiningly fixed on a substrate 121. White light generated by mixing light of each wavelength from each of the light emitting elements is irradiated to a center portion 126a of a surface to be irradiated 126 separated by a predetermined distance from the light emitting elements.

### SUMMARY OF THE INVENTION

The semiconductor light emitting device of the present invention has a small mounting area for light emitting elements and allows high-luminance, and includes light emitting elements mounted on a substrate by using a wire bonding. On one of the light emitting elements including a wire bonding portion connected to an electrode portion of the light emitting element, another plurality of light emitting elements among the light emitting elements are layered in the same state with transparent resins interposed therebetween.

With the above-described semiconductor light emitting device, a more high-luminance semiconductor light-emitting device can be obtained without increasing an occupied area of the light emitting elements arranged in a layered manner.

The other features and advantages of the present invention will be apparent from the following description.

### BRIEF OF DESCRIPTION OF THE DRAWINGS

FIG. 1 is a cross-sectional view of a semiconductor light emitting device according to a first embodiment of the present invention.

FIG. 2 is a plan view of the semiconductor light emitting device of FIG. 1.

FIG. 3 is a view showing a semiconductor light emitting device of a modified example of the semiconductor light emitting device of FIG. 1 with a cross section taken along III-III line of FIG. 1.

FIG. 4 is a cross-sectional view of a semiconductor light emitting device according to a second embodiment of the present invention.

FIG. 5 is a cross-sectional view of a semiconductor light emitting device according to a third embodiment of the present invention.

FIG. 6 is a cross-sectional view of a light source package as a conventional semiconductor light emitting device.

FIG. 7 is a side view of another conventional semiconductor light emitting device.

### DETAIL DESCRIPTION OF THE PREFERRED EMBODIMENTS

Hereinafter, embodiments of the present invention will be described with reference to the drawings.

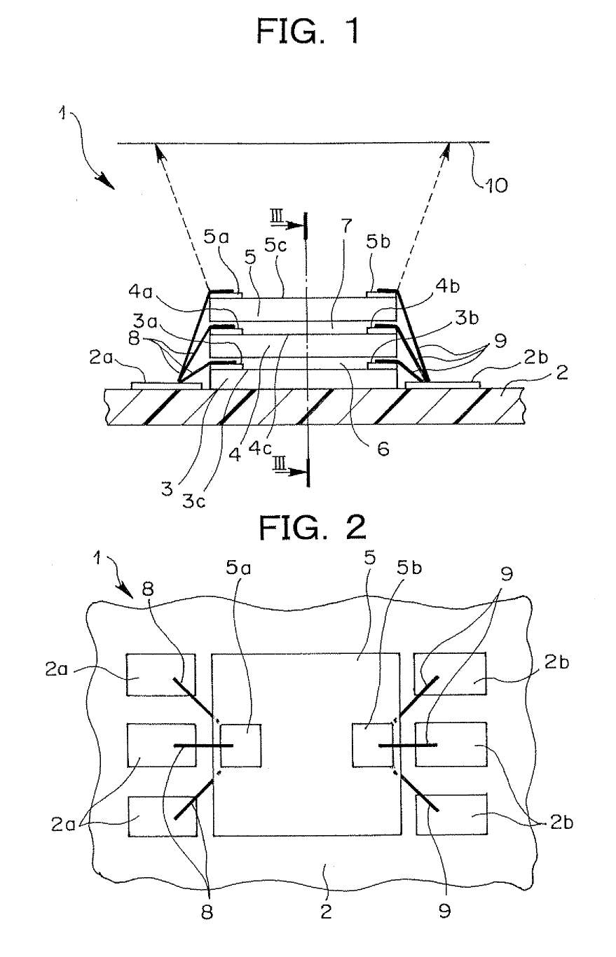

As shown in FIGS. 1 and 2, a semiconductor light emitting device 1 according to a first embodiment of the present invention includes: an electric substrate (or a package substrate) 2; a first light emitting element 3, which is a transparent light emitting element, to be die-bonded on the electric substrate 2; a second light emitting element 4, which is a transparent light emitting element, to be adhered on the light emitting element 3 with a transparent resin layer 6 interposed therebetween; and also a second light emitting element 5, which is a transparent light emitting element, to be adhered on the light emitting element 4 with a transparent resin layer 7 interposed therebetween.

The first, second, and third light emitting elements 3, 4, and 5 are formed by transparent light emitting element chips of the same size and the respective light emitting wavelengths may be the same or different from each other. On both end portions of upper surfaces 3c, 4c, and 5c of the respective light emitting elements 3, 4, and 5, bonding pads 3a, 3b, 4a, 4b, and 5a, 5b are arranged, respectively. Furthermore, on both sides of the electric substrate 2, three pairs of bonding leads 2a, 2b are arranged corresponding to the bonding pads.

To transparent resin layers 6, 7 is applied a thermal curing adhesive using an epoxy-based or silicon-based translucent resin which transmits light. Note that resin sheets composed of translucent resin may be inserted in parts of the transparent resin layers 6, 7, and the above-described respective light emitting elements be adhered and fixed using the adhesive.

In an assembly of the semiconductor light emitting device 1 having the above-described configuration, first of all, the first light emitting element 3 is fixed on the electric substrate 2 by a die-bonding method. The die-bonding method is a method of fixing the light emitting elements by an Ag paste, a metal eutectic bonding, transparent resin adhesive, or the like. Note that, when fixing the light emitting elements using the Ag paste, a layer of the Ag paste may serve also as a reflective film.

Then, the bonding pads 3a, 3b of the first light emitting element 3 and the bonding leads 2a, 2b of the electric substrate 2 are bonded by bonding wires 8, 9. Note that thin metallic wire such as of Au, Al is used as the bonding wires 8, 9.

Next, the adhesive to serve as the transparent resin layer 6 is applied on the upper surface of the first light emitting element 3, and then the second light emitting element 4 is placed on the adhesive in a layered state. Heat is applied in this state to cure the adhesive. Similarly in a fixing state of the second light emitting element 4, the bonding pads 4a, 4b and the bonding leads 2a, 2b are bonded by the bonding wires 8, 9.

Subsequently, the adhesive to serve as the transparent resin layer 6 is applied on the upper surface of the second light emitting element 4, and then the third light emitting element 5 is placed on the adhesive in a layered state. Heat is applied in this state to cure the adhesive. Similarly in a fixing state of the third light emitting element 5, the bonding pads 5a, 5b and the bonding leads 2a, 2b are bonded by the bonding wires 8, 9.

The semiconductor light emitting device 1 is completed by the above-described assembly processes. Note that, as for the completed semiconductor light emitting device 1, the whole device 1 may be sealed by a transparent resin in order to protect each of the light emitting elements and the bonding wires. Furthermore, the device may be air-tightly sealed by an optical member such as glass.

In the semiconductor light emitting device 1, when a driving voltage is applied to each of the light emitting elements 3, 4, and 5, light emitted from each of the light emitting elements 3, 4, and 5 is transmitted through the upper side transparent resin layers and light emitting elements and irradiates a surface to be irradiated 10 from the upper surface 5a of the light emitting element 5. If each of the light emitting elements 3, 4, and 5 has an emission color of the same wavelength, the surface to be irradiated is irradiated with the emission color. If each of the light emitting elements 3, 4, and 5 has emission colors of different wavelengths, the surface to be irradiated 10 is irradiated with the emission color in which lights of the respective wavelengths are mixed.

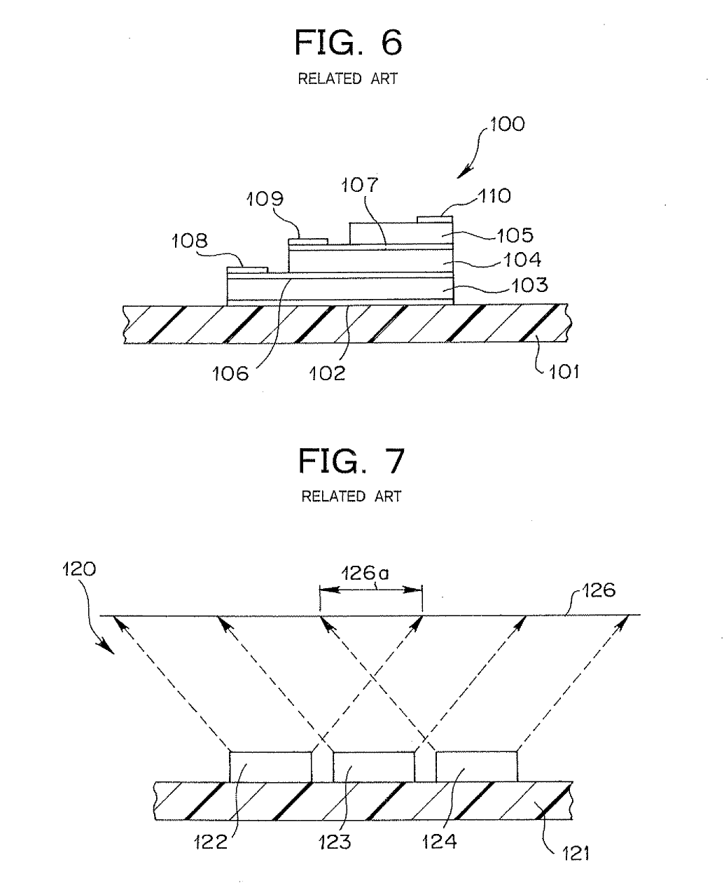

The semiconductor light emitting device 1 of the present embodiment allows the light emitting elements of a predetermined size to be arranged in a layered structure, so that there is no restriction in the size. Furthermore, compared with the conventional light source package 100, shown in FIG. 6, in which the light emitting elements of different sizes are arranged in a layered manner, the semiconductor light emitting device 1 is capable of arranging the above-described light emitting elements in a smaller area on the substrate. Accordingly, the light emitting area is increased, thereby allowing more high-luminance light source to be obtained.

Note that, though the boding pads of the respective light emitting elements are positioned at the same location in the above-described embodiment as shown in FIGS. 1 and 2, the configuration is not limited thereto, and the bonding pads can be arranged at any position on the surface of the light emitting element.

Moreover, though three light emitting elements are arranged in a layered manner in the first embodiment as shown in FIG. 1, it is possible to configure a semiconductor light emitting device in which the number of the light emitting elements arranged in a layered manner is increased or decreased as needed.

Furthermore, instead of the transparent resin layers 6, 7, which are the thermal curing adhesives in the first embodiment, an ultraviolet curing adhesive using an epoxy-based or an acrylic-based translucent resin which transmits light may be applied. If the ultraviolet curing adhesive whose curing time is short is applied, assembly time can be reduced.

Moreover, in the first embodiment, processes are required to be repeated such that one light emitting element which has been already adhered and fixed is wire bonded, and then, on the upper surface of the light emitting element, the next light emitting element is adhered and fixed. Alternatively, processes may be performed such that an adhesive is applied and a light emitting element is temporarily held mechanically in a layered state, and the light emitting element is bonded before they are adhered and fixed, then while keeping the temporary fixing state, the next layer of light emitting element is layered and bonded, and at the time that all the light emitting elements are layered and bonded, curing processing of the adhesive is performed.

Though each of the light emitting elements are the same in size in the first embodiment, the configuration is not limited thereto and the semiconductor light emitting device can be configured by arranging the light emitting elements of arbitrary sizes in a layered manner.

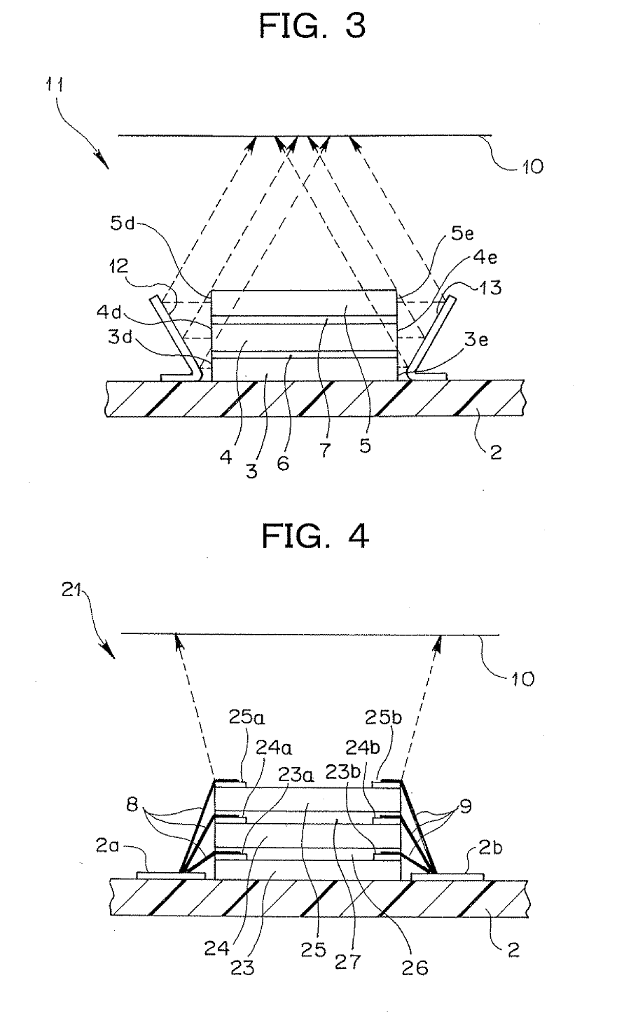

Furthermore, a reflector may be provided on side surfaces of the layered light emitting elements in order to more efficiently extract outside the lights of the light emitting elements to obtain high luminance. FIG. 3 is a view showing the semiconductor light emitting device of a modified example with a cross section taken along III-III line of FIG. 1.

In a semiconductor light emitting device 11 of the present modified example, reflectors (reflective plates) 12, 13 are arranged inclined in a state opposed to the sides of the layered light emitting elements 3, 4, and 5, as shown in FIG. 3. Note that, in the present modified example, the same components as those in the first embodiment are attached with the same reference symbols in FIG. 3.

In the semiconductor light emitting device 11, the emitting lights to be leaked laterally from the side surfaces 3d, 4d, and 5d of the layered light emitting elements 3, 4, and 5 are reflected by the reflectors 12, 13, and transmit or pass through inside or outside of the light emitting elements to reach the surface to be irradiated 10.

Accordingly, with the semiconductor light emitting device 11 of the present modified example, a more efficient and high-luminance semiconductor light emitting device than one in the first embodiment can be obtained.

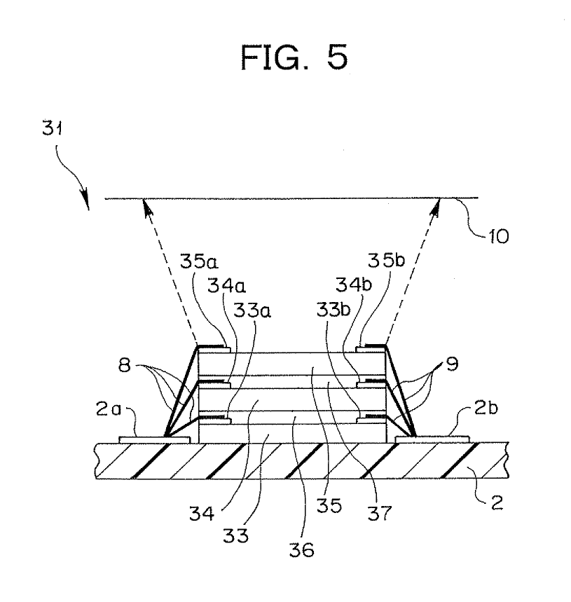

Next, a semiconductor light emitting device according to a second embodiment of the present invention is described with reference to the cross-sectional view of the semiconductor light emitting device in FIG. 4.

A semiconductor light emitting device 21 of the present embodiment includes layered three transparent light emitting elements 23, 24, and 25 which are different in light emitting wavelength and are the same in size, as shown in FIG. 4. Similarly in the case of the first embodiment, the respective light emitting elements 23, 24, and 25 includes bonding pads 23a, 23b, 24a, 24b, and 25a, 25b, respectively, and the bonding pads and the three pairs of the bonding leads 2a, 2b on the electric substrate 2 are bonded by the bonding wires 8, 9. Furthermore, similarly in the case of the first embodiment, the light emitting elements 23, 24, and 25 are arranged in a layered manner with the transparent resins interposed therebetween, to be adhered each other.

In the semiconductor light emitting device 21 of the present embodiment, the emitting lights of the respective wavelengths of the light emitting elements 23, 24, and 25 are irradiated on the surface to be irradiated 10 and illumination of composed color in which the emitting lights are mixed is performed. When, in particular, a light emitting element for emitting light in red of three primary colors of light is applied as the light emitting element 23, a light emitting element for emitting light in green of the three primary colors of light is applied as the light emitting element 24, and a light emitting element for emitting light in blue of the three primary colors of light is applied as the light emitting element 25, a white light source can be obtained.

The semiconductor light emitting device 21 of the present embodiment exhibits the same effect as that of the first embodiment, and can be used as a white or arbitrary color light source by especially selecting the wavelengths of the emitting lights of the light emitting elements 23, 24, and 25. In addition, the light emitting elements of the same size are arranged in a layered manner, thereby preventing unevenness of color from being generated even in a case where the surface to be irradiated 10 is close.

Note that the above-described modified example and the like can be applied also to the present embodiment similarly as in the case of the first embodiment.

Next, a semiconductor light emitting device according to a third embodiment of the present invention is described with reference to the cross-sectional view of the semiconductor light emitting device of FIG. 5.

A semiconductor light emitting device 31 of the present embodiment includes three transparent light emitting elements 33, 34, and 35 which are the same both in emission color and size, as shown in FIG. 4. The light emitting elements 33, 34, and 35 have bonding pads 33a, 33b, 34a, 34b, and 35a, 35b, respectively, similarly in the case of the first embodiment, and the bonding pads and the three pairs of bonding leads 2a, 2b on the electric substrate 2 are bonded by the bonding wires 8, 9. In addition, the configuration in which the light emitting elements 33, 34, and 35 are arranged in a layered manner with the transparent resins interposed therebetween and adhered is also the same in the case of the first embodiment.

In the semiconductor light emitting device 31 of the present embodiment, the emitting lights in the same color from the light emitting elements 33, 34, and 35 are irradiated onto the surface to be irradiated 10, thereby allowing high-luminance illumination to be performed.

The semiconductor light emitting device 31 of the present embodiment exhibits the same effect as that in the first embodiment, and allowing the high-luminance light source to be obtained without increasing the mounting area of the light emitting elements.

Note that the above-described modified example and the like can be applied also to the present embodiment similarly as the case in the first embodiment. By arranging many light emitting elements having the same emission color in a layered manner, in particular, it is possible to obtain high luminance proportional to the number of the layers without increasing the mounting area of the light emitting elements.

In addition, the transparent light emitting elements are used as the light emitting elements in each of the embodiments, it is needless to say that the light emitting elements are not necessarily limited to the transparent light emitting elements in a case where the emitting light from the side surface is sufficient in irradiating the surface to be irradiated.

The semiconductor light emitting device of the present invention allows the light emitting elements of the same size or arbitrary sizes to be arranged in a layered manner, so that the device does not have a restriction in size and can be utilized as a high-luminance semiconductor light emitting device capable of mounting the light emitting elements in a small area.

The present invention is not limited to the above-described embodiments, and various modifications may be implemented without departing from the scope of the invention in the implementation stages. The aforementioned embodiments contain the invention in various stages such that a plurality of disclosed components may be arbitrarily combined, thereby extracting various types of the invention.

For example, even if some of the configuration requirements are deleted out of all the configuration requirements indicated in the embodiments, the configuration in which the configuration requirements has been deleted therefrom can be extracted as an invention in the case where the problems described in the means for solving the problem can be solved and the effects described in advantages of the invention can be obtained.

What is claimed is:

1. A semiconductor light emitting device, comprising:
a substrate; and
a plurality of light emitting elements mounted on the substrate by using a wire bonding, wherein
the plurality of light emitting elements are arranged such that, on one of the light emitting elements including a bonding wire portion connected to an electrode portion of the light emitting element, another one of the light emitting elements is layered with a transparent resin interposed therebetween, and yet another one of the light emitting elements is layered thereon in the same state.

2. The semiconductor light emitting device according to claim 1, wherein the plurality of light emitting elements are configured of transparent light emitting element chips.

3. The semiconductor light emitting device according to claim 1, wherein each of the plurality of light emitting elements has a same size.

4. The semiconductor light emitting device according to claim 1, wherein each of the plurality of light emitting elements has a different size.

5. The semiconductor light emitting device according to claim 1, wherein the transparent resin is a thermal curing adhesive.

6. The semiconductor light emitting device according to claim 1, wherein the transparent resin is an ultraviolet curing adhesive.

7. The semiconductor light emitting device according to claim 1, wherein the plurality of light emitting elements are light emitting elements having at least two or more kinds of different emission colors.

8. The semiconductor light emitting device according to claim 1, wherein the plurality of light emitting elements are configured of a light emitting element of red color, a light emitting element of green color, and a light emitting element of blue color.

9. The semiconductor light emitting device according to claim 1, wherein the plurality of light emitting elements are light emitting elements having a same emission color.

10. The semiconductor light emitting device according to claim 1, further comprising
a reflective plate for reflecting light irradiated laterally from the light emitting elements, the reflective plate being lateral to the plurality of layered light emitting elements.
